(19) United States
(12) Patent Application Publication
(10) Pub. No.: US 2012/0250419 A1
(43) Pub. Date: Oct. 4, 2012

(54) METHOD OF CONTROLLING NONVOLATILE SEMICONDUCTOR MEMORY DEVICE

(75) Inventors: Hidefumi NAWATA, Kanagawa-ken (JP); Kiyomi Naruke, Mie-ken (JP)

(73) Assignee: KABUSHIKI KAISHA TOSHIBA, Tokyo (JP)

(21) Appl. No.: 13/232,259

(22) Filed: Sep. 14, 2011

(30) Foreign Application Priority Data
Mar. 28, 2011 (JP) 2011-069152

(51) Int. Cl. G11C 16/10; G11C 16/04

(52) U.S. Cl. 365/185.22; 365/185.18

(57) ABSTRACT

In one embodiment, method of controlling a semiconductor nonvolatile memory device includes determining data written to an adjacent memory cell which is adjacent to a selection memory cell in memory cells configured as a matrix, the selection memory being selected by a program operation for writing the data to the selection memory, and writing the data to the selection memory with controlling an amount of charges injected into the selection memory based on a result of determining the data.

### CROSS REFERENCE TO RELATED APPLICATION

This application is based upon and claims the benefit of priority from prior Japanese Patent Application No. 2011-069152, filed Mar. 28, 2011, the entire contents of which are incorporated herein by reference.

### FIELD

Embodiments described herein generally relate to a method of controlling a semiconductor nonvolatile memory device.

### BACKGROUND

A semiconductor nonvolatile memory device stores data by a charge amount accumulated in a floating gate (hereinafter referred to as FG). In a NAND flash memory, for example, each of memory cells includes FGs. The writing data to the memory cell and erasing data from the memory cell are executed by electron injection into the FG and electron emission from the FG, respectively. Thus, the amounts of injected electrons in the FGs are controlled thereby to set plural threshold voltage states (or data states). Recently, a NAND flash memory that stores two bits, that is, four values, in the memory cell has been developed and mass-produced.

Generally, among plural memory cells, the charge amount injected into the FGs varies due to variations in manufacturing process, a small change in voltage during operation, or the like. Thus, a threshold voltage of the memory cell has a distribution with respect to a set value. A broadening of the distribution is a factor to decrease data retention durability and in turn, to cause a malfunction of the memory, such as a read error. Particularly with recent further advances in micro fabrication of manufacturing process technology, the threshold voltage distribution of a written cell tends to be expanded by interference from the adjacent memory cells in FGs.

In typical program operation of multi-valued NAND flash memory as an example of multi-valued memory, no data is written for an erased state. In other words, there occurs no state transition, that is, no change in the threshold voltage. Thus, when there are many memory cells in the erased state (hereinafter referred to as erased cells) in the neighborhood, the memory cells are small in the amount of transition from a data-written state, that is, the amount of change in the threshold voltage.

Meanwhile, when there are only a few erased cells in the neighborhood, a memory cell makes a state transition (or a change in the threshold voltage) due to influences of adjacent cell, when writing to an adjacent memory cell takes place after the writing of data to the memory cell. Such a problem that the distribution of the data state of each written cell broadens by the data states of adjacent memory cells, has recently become noticeable.

The multi-valued memory is required to keep the broadening of the threshold voltage distribution of a written cell narrower than a binary memory, because of restrictions on operating characteristics of the multi-valued memory. Therefore, the above problem is particularly serious for multi-valued memory.

### BRIEF DESCRIPTION OF THE DRAWINGS

FIG. 1 is a flowchart showing program operation in a method for controlling a semiconductor nonvolatile memory device according to a first embodiment;

FIGS. 2A and 2B are conceptual drawings showing the program operation in the method for controlling the semiconductor nonvolatile memory device according to the first embodiment;

FIG. 3 is a conceptual drawing showing an example of a state transition (or a change in threshold voltage distribution) in data writing of the semiconductor nonvolatile memory device according to the first embodiment;

FIGS. 4A to 4C are conceptual drawings showing changes in the threshold voltage distribution in the program operation in the method for controlling the semiconductor nonvolatile memory device according to the first embodiment;

FIG. 5 is a flowchart showing program operation in a method for controlling a semiconductor nonvolatile memory device according to a second embodiment; and

FIGS. 6A and 6B are conceptual drawings showing the program operation in the method for controlling the semiconductor nonvolatile memory device according to the second embodiment.

### DETAILED DESCRIPTION

In one embodiment, method of controlling a semiconductor nonvolatile memory device, includes determining data written to an adjacent memory cell which is adjacent to a selection memory cell in memory cells configured as a matrix, the selection memory being selected by a program operation for writing the data to the selection memory, and writing the data to the selection memory with controlling an amount of charges injected into the selection memory based on a result of determining the data.

### First Embodiment

Embodiments will be described below with reference to the drawings.

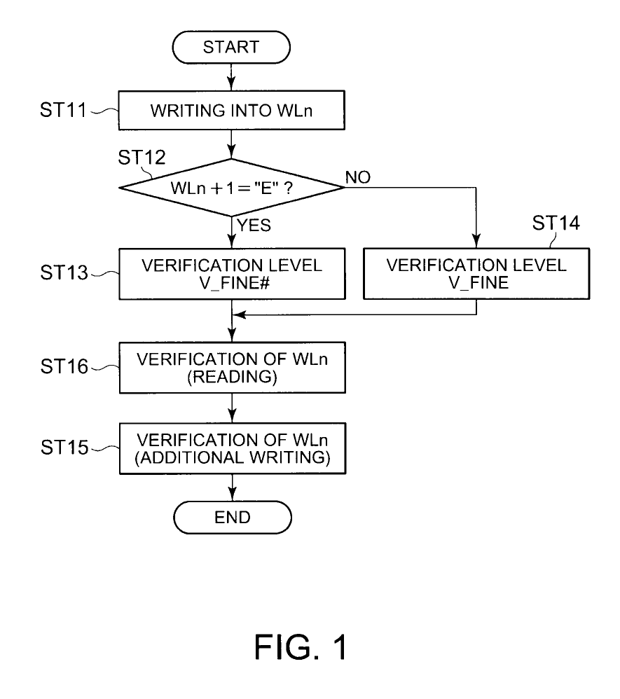

FIG. 1 is a flowchart showing program operation in a method for controlling a semiconductor nonvolatile memory device according to a first embodiment. FIG. 1 shows processing of NAND flash memory involved in the program operation, and in the program operation, data is written to a selected memory cell WLn corresponding to a word line WLn.

The method for controlling the semiconductor nonvolatile memory device according to the first embodiment includes an initial writing step ST11, a decision step ST12, a setting step consisting of a first setting step ST13 and a second setting step ST14, a first verification step ST16, and a second verification step ST15.

The initial writing step ST11 performs initial writing to the memory cell WLn. The decision step ST12 makes a decision on data of a memory cell WLn+1 adjacent to the memory cell WLn. The first setting step ST13 and the second setting step ST14 set a verification level based on a result of the decision of the decision step ST12. The first verification step ST16 reads the memory cell WLn as first verification, based on the verification level set by the first setting step ST13 and the second setting step ST14. The second verification step ST15 performs additional writing to the memory cell WLn as second verification.

In the initial writing step ST11, electrons are injected into an FG by a typical method, according to data to be written to the selected memory cell WLn. This effects a change in a threshold voltage of the memory cell WLn. In the case of four-valued NAND flash memory, for example, the threshold voltage of the memory cell WLn transitions to an “A” state when data “1” is written thereto, the threshold voltage of the memory cell WLn transitions to a “B” state when data “2” is written thereto, and the threshold voltage of the memory cell WLn transitions to a “C” state when data “3” is written thereto.

In the NAND flash memory, all memory cells of a target block are erased prior to the program operation. At this time, electrons are not injected into the FG of the memory cell WLn in which data “0” is to be written. This state is called an “E” state. In this case, therefore, the threshold voltage remains in the “E” state.

In the decision step ST12, a decision is made as to whether or not data to be written to the memory cell WLn+1 adjacent to the memory cell WLn is “0,” that is, the memory cell WLn+1 remains in the “E” state.

When the result of the decision of the decision step ST12 is “Yes” that is, when the data to be written to the memory cell WLn+1 is “0” in the first setting step ST13, a read voltage level (or the verification level) of the word line for the memory cell WLn is set to V_FINE# that is a higher level than an usual level.

Instead, when the result of the decision of the decision step ST12 is “No” that is, when the data to be written to the memory cell WLn+1 is anything other than “0” in the second setting step ST14, the read voltage level of the word line for the memory cell WLn is set to V_FINE (<V_FINE#) that is a usual level.

In other words, one of different read voltages is applied to the word line for the memory cell WLn, based on the result of the decision of the decision step ST12.

In the first verification step ST16, reading of the memory cell WLn is performed according to the verification level set by the first setting step ST13 or the second setting step ST14. As a result of the case mentioned above, a decision is made as to whether the verification succeeds or fails. When the verification fails, the second verification step ST15 is performed.

In the second verification step ST15, additional writing is executed using the verification level obtained by the first verification step ST16. In other words, the additional writing to the memory cell WLn is performed by controlling the amount of electrons injected into the FG, based on the data to be written to the memory cell WLn+1.

Consequently, when the data to be written to the memory cell WLn+1 is “0” a larger amount of electrons are injected into the FG of the memory cell WLn, than when data other than “0” is written. Immediately after the completion of the additional writing to the memory cell WLn, the threshold voltage of the memory cell WLn becomes relatively high, as compared to when the data to be written to the memory cell WLn+1 is anything other than “0”.

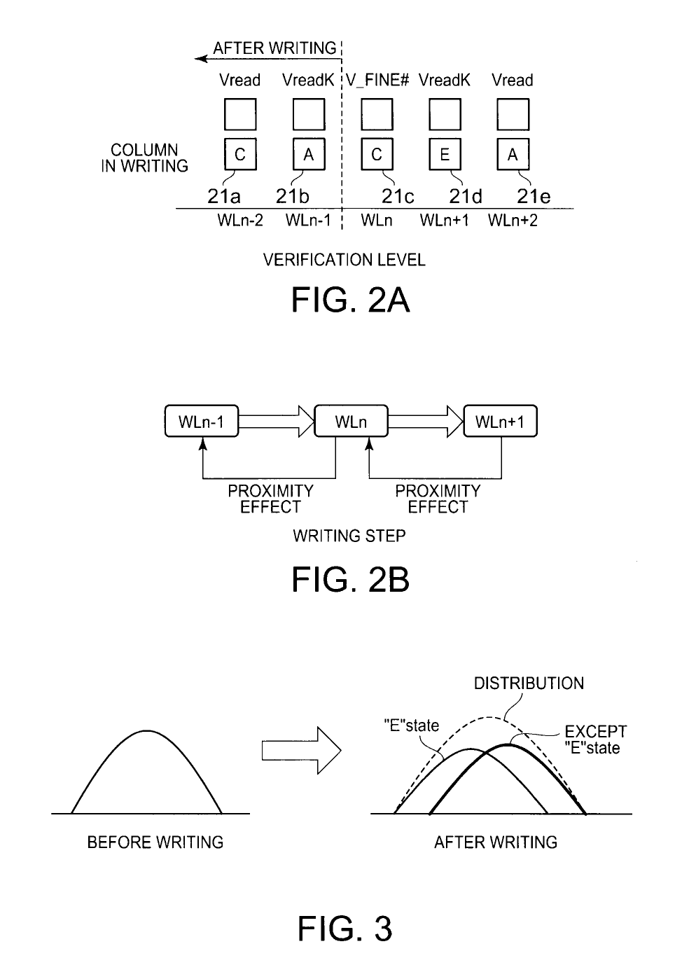

FIGS. 2A and 2B are conceptual drawings showing the program operation in the method for controlling the semiconductor nonvolatile memory device according to the first embodiment. FIGS. 2A and 2B show portions of the four-valued NAND flash memory involved in the program operation, corresponding to FIG. 1. In the program operation, data is written in sequence to plural memory cells 21a to 21e arranged in a selected column (or a write column).

In FIG. 2A, first, data writing on and before a memory cell WLn−1 of the write column is completed. For example, there are shown the voltage levels of the word lines in the first verification step ST16 at the time of the writing of the data “3” to the memory cell WLn. The memory cells 21a, 21b, 21c, 21d, 21e of the write column correspond to word lines WLn−2, WLn−1, WLn, WLn+1, WLn+2, respectively. The data “3” for the “C” state is written to the memory cell 21a, and the data “1” for the “A” state is written to the memory cell 21b. In addition, it is expected that the data “3” for the “C” state will be written to the memory cell 21c, the data “0” for the “E” state will be written to the memory cell 21d, and the data “1” for the “A” state will be written to the memory cell 21e.

FIG. 2B is the conceptual drawing showing the state of influence of an adjacent effect of an adjacent memory cell, when data is written in sequence to the memory cells arranged in the write column. As shown in FIG. 2B, the program operation in the method for controlling the semiconductor nonvolatile memory device executes data writing in sequence to the plural memory cells WLn−1, WLn, WLn+1 in the selected write column. Thus, at the completion of the data writing to the memory cell WLn, the threshold voltage of the memory cell WLn−1 makes a transition by the influence of the adjacent effect of the memory cell WLn. Also, at the completion of the data writing to the memory cell WLn+1, the threshold voltage of the memory cell WLn makes a transition by the influence of the adjacent effect of the memory cell WLn+1.

Given is a specific example of the transition of the threshold voltage of the memory cell by the influence of the adjacent effect. As shown for example in FIG. 2A, at the completion of the data writing to the memory cell 21c, the memory cell 21c enters the “C” state. By the adjacent effect, therefore, the threshold voltage of the memory cell 21b makes a transition from a value at the completion of the writing of the data (“1”) to the memory cell 21b to higher values.

On the other hand, at the completion of the data writing to the memory cell 21d, the memory cell 21d remains in the “E” state. Thus, the threshold voltage of the memory cell 21c does not change from a value immediately after the completion of the writing of the data (“3”) to the memory cell 21c, so that the transition of the threshold voltage does not occur.

In the method for controlling the semiconductor nonvolatile memory device according to the first embodiment, a correction is made on a memory cell in the second verification step in advance to amend a difference in the amount of transition of the threshold voltage by the influence of the adjacent effect. In other words, if the adjacent memory cell to which data is to be next written remains in the “E” state after the data writing, the verification level is raised in advance (to V_FINE#) to perform additional writing. As a result, the amount of charge injected into the FG of the memory cell is controlled in relation to the adjacent memory cell to which data is to be next written, which affects the threshold voltage to transition to the same extent as when the adjacent memory cell transitions to any state other than the “E” state.

Incidentally, the data to be next written is stored for example in a latch circuit or the like in a sense amplifier. In the case of FIG. 2A, at the time of the writing of data to the memory cell 21c, data “E” of the memory cell 21d is stored in the latch circuit. The decision step ST12 of FIG. 1 is performed based on the data in the latch circuit.

FIG. 3 is a conceptual drawing showing as an example of a state transition, or a change in threshold voltage distribution, in data writing of the semiconductor nonvolatile memory device according to the first embodiment.

FIG. 3 shows by way of example the threshold voltage distribution when data other than “0” is written to the memory cell WLn by a typical method, and the threshold voltage distribution of the memory cell WLn when data is written to the memory cell WLn+1 (or the adjacent memory cell WLn+1) adjacent to the memory cell WLn, by comparison.

In FIG. 3, the horizontal axis indicates a threshold voltage (V) of the memory cell, and the vertical axis indicates the number of memory cells at the threshold voltage. An angled waveform shown by the solid line on the left side shows the threshold voltage distribution (or the original distribution) of the memory cell WLn at the completion of the data writing to the memory cell WLn, and three angled waveforms on the right side show the threshold voltage distributions of the memory cell WLn after the completion of the data writing to the adjacent memory cell WLn+1. As the original distribution, the waveform of a general threshold voltage distribution is shown for explanation to facilitate an understanding of the change in the threshold voltage during the program operation. Actually, such a threshold voltage distribution does not occur throughout the memory cells. In other words, the original distribution shows the threshold voltage distribution of the memory cell WLn on the assumption that the transition of the threshold voltage by the adjacent effect of the adjacent memory cell WLn+1 is absent.

When the memory cell WLn+1 is in the “E” state at the completion of the data writing to the adjacent memory cell WLn+1, little transition of the threshold voltage occurs as shown by the solid-line angled waveform on the right side. On the other hand, if the adjacent memory cell WLn+1 is in any state other than the “E” state, the transition of the threshold voltage from the original distribution to higher values occurs as shown by the heavy-solid-line angled waveform on the right side. Thus, the threshold voltage distribution of the overall memory becomes a wider distribution, as compared to the original distribution, as shown by the dotted-line angled waveform on the right side.

Such an adjacent effect can be simply expressed in equation form as: Z=X+α(Y−Yi), where Z denotes the threshold voltage of the memory cell WLn (after the data writing to WLn+1), X denotes the threshold voltage of the memory cell WLn (immediately after the data writing to WLn), Y denotes the threshold voltage of the memory cell WLn+1 (after the data writing to WLn+1), Yi denotes the threshold voltage of the memory cell WLn+1 (in an initial state), and a denotes a coefficient.

For example when the data to be written to the memory cell WLn+1 is “0” (or is for the “E” state), Z becomes equal to X (Z=X) since Y is equal to Yi (Y=Yi). The threshold voltage of the memory cell WLn makes a little transition. On the other hand, when the data to be written to the memory cell WLn+1 is anything other than “0” (or is for any state other than the “E” state), the threshold voltage of the memory cell WLn makes a transition to a higher value by the amount of α(Y−Yi) since Y is not equal to Yi (Y≠Yi).

Thus, as shown in FIG. 1, when the adjacent memory cell WLn+1 remains in the “E” state, in the verification of the memory cell WLn, the verification level is raised to perform the additional writing, so as to effect the transition of the threshold voltage to the same extent as α(Y−Yi). Such a method is used to make a correction for the influence of the adjacent effect and thereby enable narrowing the threshold voltage distribution of the overall memory cell, as shown in FIG. 3.

When the adjacent memory cell WLn+1 is in the “E” state during reading, the memory cell WLn may be corrected. For example, a method is to apply a higher voltage than other word lines to the word line WLn+1 when the adjacent memory cell WLn+1 remains in the “E” state. However, the correction for the influence of the adjacent memory cell WLn+1 during the reading requires that data of the adjacent memory cell WLn+1 be read for each read operation. Consequently, the read operation becomes slow. Meanwhile, in the embodiment, the correction is made for the influence of the adjacent memory cell WLn+1 during writing, and thereby, no correction needs to be made for the influence of the adjacent memory cell WLn+1 during reading. Consequently, a read time becomes short. Thus, a great advantageous effect can be achieved particularly when data reading is performed many times after the data is once written to the memory cell WLn.

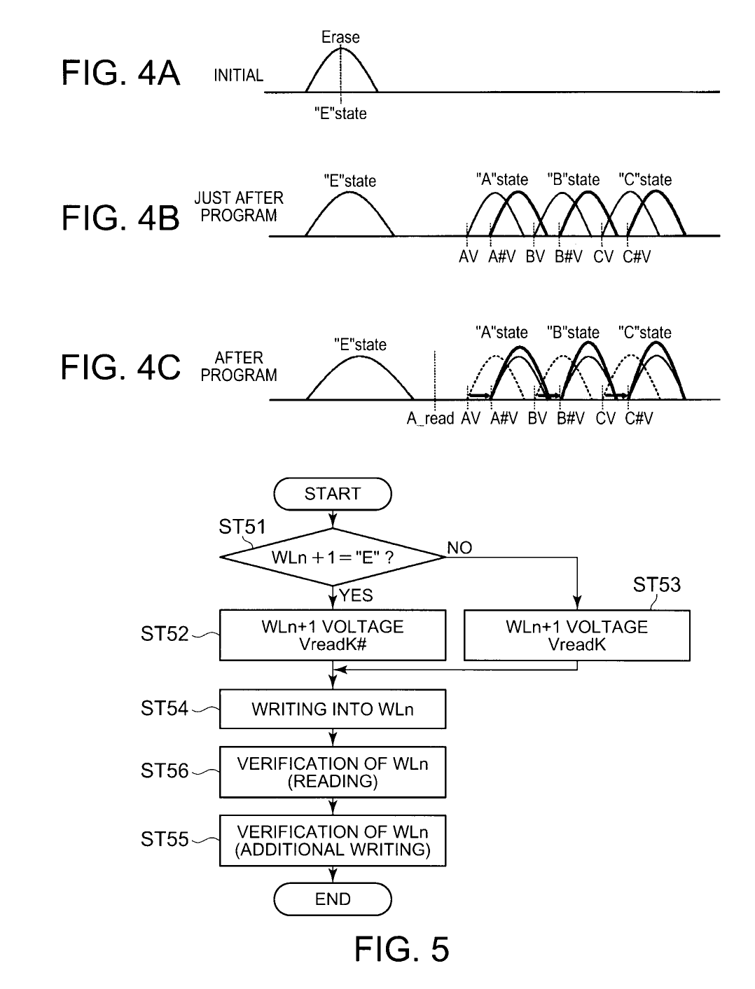

FIGS. 4A to 4C are conceptual drawings showing changes in the threshold voltage distribution in the program operation in the method for controlling the semiconductor nonvolatile memory device according to the first embodiment. In FIGS. 4A to 4C, the horizontal axis indicates the threshold voltage of the memory cell, and the vertical axis indicates the number of memory cells at the threshold voltage.

FIG. 4A shows the threshold voltage distribution in the initial state in which all memory cells are in an erased state. FIG. 4B shows the threshold voltage distribution in a state immediately after the data writing to the memory cell WLn, that is, in the state of WLn after the program operation. FIG. 4C shows the threshold voltage distribution in a state after the data writing to the memory cell WLn+1, that is, in the state of WLn+1 after the program operation. Here, the threshold voltage distributions in data states (i.e. the “E” state, the “A” state, the “B” state, and the “C” state) of the four-valued NAND flash memory are shown as one conceptual drawing for the sake of simplicity of the drawings. FIG. 4B shows a general threshold voltage distribution for explanation to facilitate the understanding of the change in the threshold voltage during the program operation. Actually, such a threshold voltage distribution does not occur throughout the memory cells.

In the four-valued NAND flash memory, data is erased from all memory cells of a target block to be written, before the program operation. As shown in FIG. 4A, the threshold voltage distribution is in the “E” state alone.

In this state, the data writing to the memory cell WLn is performed using the method shown in FIG. 1. The threshold voltage of the memory cell WLn makes a transition according to the written data. The general threshold voltage distribution of the memory cell WLn makes a transition to each state, as shown in FIG. 4B. In other words, when the memory cell WLn+1 adjacent to a memory cell WLn in the “A” state having the data “1” written thereto enters any state other than the “E” state, the memory cell WLn makes a transition to the general threshold voltage distribution starting at a threshold voltage AV. In FIG. 4B, the threshold voltage distribution is shown by the solid line, and will be hereinafter called the threshold voltage distribution AV. When the memory cell WLn+1 adjacent to a memory cell WLn in the “A” state having the data “1” written thereto remains in the “E” state, the memory cell WLn makes a transition to the general threshold voltage distribution starting at a threshold voltage A#V. In FIG. 4B, the threshold voltage distribution is shown by the heavy solid line, and will be hereinafter called the threshold voltage distribution A#V.

Also, when the adjacent memory cell WLn+1 adjacent to a memory cell WLn in the “B” state having the data “2” written thereto enters any state other than the “E” state, the memory cell WLn makes a transition to the general threshold voltage distribution starting at a threshold voltage BV. In FIG. 4B, the threshold voltage distribution is shown by the solid line, and will be hereinafter called the threshold voltage distribution BV. When the memory cell WLn+1 adjacent to a memory cell WLn in the “B” state having the data “2” written thereto remains in the “E” state, the memory cell WLn makes a transition to the general threshold voltage distribution starting at a threshold voltage B#V. In FIG. 4B, the threshold voltage distribution is shown by the heavy solid line, and will be hereinafter called the threshold voltage distribution B#V. When the memory cell WLn+1 adjacent to a memory cell WLn in the “C” state having the data “3” written thereto enters in any state other than the “E” state, the memory cell WLn makes a transition to the general threshold voltage distribution starting at a threshold voltage CV. In FIG. 4B, the threshold voltage distribution is shown by the solid line, and will be hereinafter called the threshold voltage distribution CV. When the memory cell WLn+1 adjacent to a memory cells WLn in the “C” state having the data “3” written thereto remains in the “E” state, the memory cell WLn makes a transition to a virtual threshold voltage distribution starting at a threshold voltage C#V. In FIG. 4B, the threshold voltage distribution is shown by the heavy solid line, and will be hereinafter called the threshold voltage distribution C#V.

When the data writing to the memory cell WLn+1 is executed, the threshold voltage distributions AV, BV and CV of the memory cell WLn shown by the dotted lines in FIG. 4C make transitions to higher threshold voltages by the influence of the adjacent effect of the memory cell WLn+1 on the memory cell WLn, as shown in FIG. 4C.

In other words, the threshold voltage distribution A#V is subjected in advance to the additional writing so as to effect the transition of the threshold voltage to the same extent as the amount of transition of the threshold voltage, α(Y−Yi), corresponding to the influence of the adjacent effect. Consequently, the threshold voltage distribution AV makes a transition to a position substantially overlapping the threshold voltage distribution A#V, by the influence of the adjacent effect of the memory cell WLn+1, and as a result, the distribution range of the threshold voltage distribution in the “A” state becomes narrow as shown by the heavy solid line. Likewise, the threshold voltage distribution BV makes a transition to a position substantially overlapping the threshold voltage distribution B#V, and the threshold voltage distribution CV makes a transition to a position substantially overlapping the threshold voltage distribution C#V, so that the distribution ranges of the threshold voltage distributions in the “B” state and the “C” state also become narrow.

The memory cells having the threshold voltage distributions A#V, B#V and C#V are memory cells adjacent to the memory cell WLn+1 to which the data “0” for the “E” state is written. Thus, after the completion of the data writing to the memory cell WLn+1, the threshold voltage makes little transition, and the threshold voltage distributions AV, BV and CV alone make transitions to higher values.

According to the above-described first embodiment, the correction is made for the influence of the adjacent effect of the adjacent memory cell, so that the distribution range of the threshold voltage distribution of the memory cell can become narrow. Therefore, the semiconductor nonvolatile memory device having a reduced data error rate and hence high reliability can be provided.

Also, according to the above-described first embodiment, the data error rate can be reduced, thus enabling a reduction in the number of packaged ECCs (Error Correcting Codes) recovered and hence an improvement in reading performance or cost-competitiveness.

In the above description of the first embodiment, the initial writing step ST11 is executed before the decision step ST12. However, it is to be understood that the embodiment is not so limited. For example, the initial writing step ST11, the first verification step ST16 and the second verification step ST15 may be executed following after the decision step ST12 and the setting steps ST13, ST14 of setting the verification level.

Also, in the above description of the first embodiment, at the time of the data writing to the memory cell WLn, a decision is made as to whether or not the data to be written to the memory cell WLn+1 is for the “E” state. However, it is to be understood that the embodiment is not so limited. For example, the additional writing to the memory cell WLn may be executed after the completion of the data writing to the memory cell WLn+1. Alternatively, the decision step ST12 of the memory cell WLn+1, the setting steps ST13, ST14 of setting the verification level of WLn, and the first verification step ST16 and the second verification step ST15 of the memory cell WLn may be executed as background jobs to other operations. Consequently, it is not required that the data to be next written is stored in the latch circuit or the like. Thus, write operation can be simplified. Also, the write operation can be speeded up.

Also, situations may arise where, until the verification succeeds, the reading is performed as the first verification and the additional writing is performed as the second verification. In such cases, in all first verifications, a voltage set by the first setting step ST13 and the second setting step ST14 of setting the verification level applied to the memory cell WLn may be used.

### Second Embodiment

FIG. 5 is a flowchart showing program operation in a method for controlling a semiconductor nonvolatile memory device according to a second embodiment. FIG. 5 shows processing of NAND flash memory involved in the program operation, and in the program operation, data is written to a selected memory cell (WLn).

The method for controlling the semiconductor nonvolatile memory device according to the second embodiment includes a decision step ST51, a first setting step ST52, a second setting step ST53, an initial writing step ST54, a first verification step ST56, and a second verification step ST55.

The decision step ST51 makes a decision on data of a memory cell WLn+1 adjacent to the memory cell WLn. The first setting step ST52 and the second setting step ST53 set a word line voltage (hereinafter called a “read voltage”) of the memory cell WLn+1, based on a result of decision of the decision step ST51. The initial writing step ST54 performs initial writing to the memory cell WLn. The first verification step ST56 performs verification (or reading) of the memory cell WLn, based on the read voltage set by the setting steps ST52, ST53. The second verification step ST55 performs verification (or additional writing) of the memory cell WLn.

In the decision step ST51, a decision is made as to whether or not data to be written to the memory cell WLn+1 adjacent to the memory cell WLn is “0” (or is for the “E” state). Incidentally, the data to be written to the memory cell WLn+1 is stored for example in a latch circuit or the like in a sense amplifier.

When the result of the decision of the decision step ST51 is “Yes,” that is, if the data to be written to the memory cell WLn+1 is “0,” in the first setting step ST52, the read voltage of the word line for the memory cell WLn+1 is set to VreadK# higher than usual.

Also, when the result of the decision of the decision step ST51 is “No,” that is, when the data to be written to the memory cell WLn+1 is anything other than “0,” in the second setting step ST53, the read voltage of the word line for the memory cell WLn+1 is set to VreadK (<VreadK#) that is a usual level.

In other words, at the time of the reading by the first verification step ST56, different read voltages are applied to the word line for the memory cell WLn+1, based on the result of the decision of the decision step ST51.

In the initial writing step ST54, electrons are injected into an FG by using a typical method, according to data written to the selected memory cell WLn. This effects a change in a threshold voltage of the memory cell WLn. In the case of four-valued NAND flash memory, for example, the threshold voltage of the memory cell WLn transitions to an “A” state when data “1” is written thereto, the threshold voltage of the memory cell WLn transitions to a “B” state when data “2” is written thereto, and the threshold voltage of the memory cell WLn transitions to a “C” state when data “3” is written thereto.

In the NAND flash memory, all memory cells of a target block are erased (or are brought into the “E” state) before the program operation, and electrons are not injected into the FG of the memory cell WLn to which data “0” is to be written. In this case, therefore, the threshold voltage remains in the “E” state.

In the first verification step ST56, reading of the memory cell WLn is performed by applying the read voltage of the memory cell WLn+1 set by the first setting step ST52 or the second setting step ST53. As a result of the case mentioned above, a decision is made as to whether the verification succeeds or fails. Then, if the verification fails, the second verification step ST55 is performed.

In the second verification step ST55, additional writing is executed based on a result of the reading using the read voltage (or the word line voltage of the memory cell WLn+1) set by the first setting step ST52 or the second setting step ST53. In other words, the additional writing to the memory cell WLn is performed while controlling the amount of electrons injected into the FG, based on the data to be written to the memory cell WLn+1.

The word line voltages VreadK, VreadK# of the memory cell WLn+1 are at voltage level sufficient for the memory cell to enter an ON state (or a conductive state), regardless of the data written to the memory cell, that is, regardless of the threshold voltage of the memory cell. Also, VreadK# is set higher than VreadK. Thereby, at VreadK#, the transition of the threshold voltage occurs so that a difference from VreadK is equivalent to α(Y−Yi) of the adjacent effect of the first embodiment shown in FIG. 3.

Consequently, when the data to be written to the memory cell WLn+1 is “0” a larger amount of electrons are injected into the FG of the memory cell WLn than when the data is anything other than “0”. Immediately after the completion of the additional writing to the memory cell WLn, the threshold voltage of the memory cell WLn is higher than that when the data to be written to the memory cell WLn+1 is anything other than “0”.

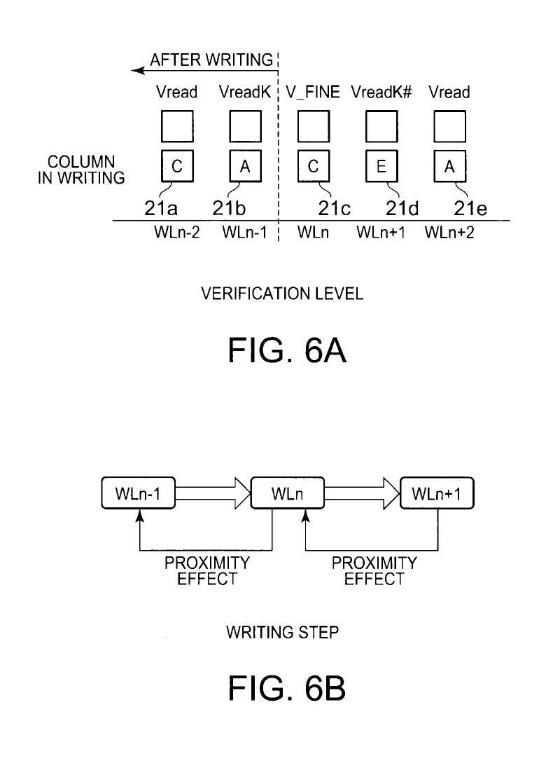

FIGS. 6A and 6B are conceptual drawings showing the program operation in the method for controlling the semiconductor nonvolatile memory device according to the second embodiment. Here, FIGS. 6A and 6B show portions of the four-valued NAND flash memory involved in the program operation, corresponding to FIG. 5, and in the program operation, data is written in sequence to plural memory cells (21a to 21e) arranged in a selected column (or a write column).

In FIG. 6A, first, data writing on and before a memory cell WLn−1 of the write column is completed. FIG. 6A is the conceptual drawing showing the voltage levels of the word lines in the first verification step ST56 at the time of the data writing to the memory cell WLn. Also, FIG. 6B is the conceptual drawing showing the state of influence of an adjacent effect of an adjacent memory cell, when data is written in sequence to the memory cells arranged in the write column.

Since the flow of the program shown in FIGS. 6A and 6B, the data used by way of example, and the like are the same as those of the first embodiment, detailed description will be omitted, using the same reference numerals and names. As described with reference to FIG. 5, the voltage applied to the memory cell WLn, and the voltage applied to the word line of the memory cell WLn+1 are different from those in the first embodiment. In other words, in the second embodiment, in the first verification step ST56 of the memory cell WLn, V_FINE of the usual level is used as the verification level, regardless of the data to be written to the memory cell WLn+1. The word line voltage of the memory cell WLn+1 is set to VreadK or VreadK# according to the data to be written to the memory cell WLn+1 thereby to execute the verification of the memory cell WLn.

In the method for controlling the semiconductor nonvolatile memory device according to the second embodiment, a correction is made on a memory cell in the second verification step ST55 in advance so as to amend a difference in the amount of transition of the threshold voltage by the influence of the adjacent effect. In other words, when the memory cell to which data is to be next written remains in the “E” state, the word line voltage of the adjacent memory cell is set higher than usual (or is set to VreadK#) to perform additional writing. Consequently, when the memory cell to which the data is to be next written enters any state other than the “E” state, the amount of charge injected into the FG of the memory cell is controlled so as to effect the transition of the threshold voltage to the same extent as the state other than the “E” state.

According to the above-described second embodiment, a correction is made for the influence of the adjacent effect of the adjacent memory cell, so that the width (or the distribution range) of the threshold voltage distribution of the memory cell can become narrow. Therefore, the semiconductor nonvolatile memory device having a reduced data error rate and hence high reliability can be provided.

Also, according to the above-described second embodiment, the data error rate can be reduced, thus enabling a reduction in the number of packaged ECCs (Error Correcting Codes) recovered and hence an improvement in reading performance or cost-competitiveness.

Also, a correction is made for the influence of the adjacent memory cell WLn+1 during the writing, and thereby, no correction needs to be made for the influence of the adjacent memory cell WLn+1 during the reading. Consequently, a read time becomes short. A great advantageous effect can be achieved, particularly when data reading is performed many times after data is once written to the memory cell WLn.

In the above description of the second embodiment, the initial writing step ST54 is executed after the first setting step ST52 and the second setting step ST53. However, it is to be understood that the embodiment isnot so limited. For example, the initial writing step ST54 may be first executed, as is the case with the first embodiment.

Also, the first verification step ST56 and the second verification step ST55 may be performed until the verification succeeds. In that case, in all first verification steps ST56, the voltage set by the first setting step ST52 and the second setting step ST53 may be used as the read voltage applied to the memory cell WLn+1.

Also, in the above description of the second embodiment, at the time of the data writing to the memory cell WLn, a decision is made as to whether or not the data to be written to the memory cell WLn+1 is for the “E” state. However, it is to be understood that the invention is not so limited. For example, the additional writing to the memory cell WLn may be executed after the completion of the data writing to the memory cell WLn+1. Alternatively, the decision step ST51 of the memory cell WLn+1, the first setting step ST52 and the second setting step ST53 of WLn+1, and the first verification step ST56 and the second verification step ST55 of the memory cell WLn may be executed as background jobs to other operations. Consequently, it is not required that the data to be next written is stored in the latch circuit or the like. Thus, the write operation can be simplified. Also, the write operation can be speeded up.

Further, in the above description of the first embodiment and second embodiment, the four-valued NAND flash memory is used as an example. However, it is to be understood that the embodiments are not so limited. In principle, the embodiments may be applied to a semiconductor nonvolatile memory device such that the threshold voltage distribution becomes wide by the influence of the adjacent effect.

Also, the embodiments may be adapted for what is called a MONOS type memory cell including an insulating film to trap charge, as a charge storage layer instead of a floating gate electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of controlling a nonvolatile semiconductor device, comprising:
determining data written to an adjacent memory cell which is adjacent to a selection memory cell in memory cells configured as a matrix; and
writing the data to the selection memory with controlling an amount of charges injected into the selection memory based on a result of determining the data.

2. The method of claim 1, further comprising;
writing the data initially before determining the data.

3. The method of claim 2, wherein
the selection memory is set as a state selected from four states in the writing the data initially.

4. The method of claim 1, further comprising;
writing the data initially is executed between the determining the data and writing the data.

5. The method of claim 2, wherein
determining the data and writing the data are executed as a background job in performing a program action of another memory cell after completing writing the data initially.

6. The method of claim 1, wherein
determining the data and writing the data are executed before writing the data to the adjacent memory cell.

7. The method of claim 1, wherein
writing the data includes reading a first verification by applying a first voltage to a word line corresponded to the adjacent memory cell based on the result of the determining the data, the first voltage being different from a second voltage applied to the selection memory cell.

8. The method of claim 7, wherein
writing the data includes writing first additional data to the selection memory cell after finishing reading the verification.

9. The method of claim 8, wherein
the additional data in writing the first additional data is determined based on an adjacent effect due to the adjacent memory cell.

10. The method of claim 1, wherein
writing the data includes reading a second verification by applying a third voltage to a word line corresponded to the selection memory cell based on the result of determining the data.

11. The method of claim 10, wherein
writing the data includes writing a second additional data to the selection memory cell after finishing reading the second verification.

12. The method of claim 11, wherein
the additional data in writing the second additional data is determined based on an adjacent effect due to the adjacent memory cell.

13. The method of claim 9, wherein
the adjacent effect is represented by an equation
Z=X+α(Y−Yi),
where Z is a threshold voltage of the selection memory cell after writing to the adjacent memory cell,
X is a threshold voltage of the selection memory cell after writing to the selection memory cell,
Y is a threshold voltage of the adjacent memory cell after writing to the adjacent memory cell, and
α is a coefficient.

14. The method of claim 1, wherein
the nonvolatile semiconductor device is constituted with four-value NAND-type flash memory cells.

15. The method of claim 1, wherein
the nonvolatile semiconductor device is constituted with MONOS-type memory cells.
